(19) United States
(12) Patent Application Publication
(10) Pub. No.: US 2026/0173845 A1
(43) Pub. Date: Jun. 18, 2026

(54) METAL VIA STRUCTURE ON METAL ALLOY BASE

(71) Applicant: International Business Machines Corporation, Armonk, NY (US)

(72) Inventors: Oscar van der Straten, Guilderland Center, NY (US); Pratap Deshmukh, Albany, NY (US); Chih-Chao Yang, Glenmont, NY (US)

(21) Appl. No.: 18/985,920

(22) Filed: Dec. 18, 2024

(51) Int. Cl. H01L 23/522; H01L 21/768; H01L 23/528

(52) U.S. Cl. CPC H10W 20/42; H10W 20/435; H10W 20/039

(57) ABSTRACT

A structure is provided that includes a robust metal via structure that is positioned on a metal alloy base. The robust metal via structure includes a first via portion and a second via portion, the second via portion is located above, and in direct contact with the first via portion, and the first via portion is in direct contact with the metal alloy base. The first via portion includes a first metal liner that is present along a sidewall thereof, while the second via portion includes a second metal liner that is present along a sidewall thereof.

### BACKGROUND

The present application relates to semiconductor technology, and more particularly to a structure including a metal via structure that is located on a metal alloy base.

Generally, semiconductor devices include a plurality of circuits which form an integrated circuit fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene wiring, i.e., interconnect, structures.

Within typical interconnect structures, electrically conductive metal vias run perpendicular to the semiconductor substrate and electrically conductive metal lines run parallel to the semiconductor substrate. Typically but not necessarily always, an electrically conductive metal via is present beneath an electrically conductive metal line and both features are embedded within an interlayer dielectric material layer.

### SUMMARY

A structure is provided that includes a robust metal via structure that is positioned on a metal alloy base. The robust metal via structure includes a first via portion and a second via portion, the second via portion is located above, and in direct contact with, the first via portion, and the first via portion is in direct contact with the metal alloy base. The first via portion includes a first metal liner that is present along a sidewall thereof, while the second via portion includes a second metal liner that is present along a sidewall thereof. The metal via structure of the present application has a lower via resistance and extends the scalability of metal via structures due to an enlarged process window for low via resistance.

In one embodiment of the present application, the structure includes a metal via structure located on a metal alloy base. The metal via structure includes a first via portion and a second via portion in which the first via portion is in direct physical contact with the metal alloy base, and the second via portion is located above, and is in direct physical contact, with the first via portion.

In another embodiment of the present application, the structure includes a metal alloy base located on an electrically conductive structure, and a metal via structure embedded in an interlayer dielectric (ILD) layer and located on the metal alloy base. The metal via structure of this embodiment includes a first via portion and a second via portion in which the first via portion is in direct physical contact with the metal alloy base, and the second via portion is located above, and is in direct physical contact with, the first via portion. The structure further includes a first metal liner located on a sidewall and a topmost surface of the first via portion of the metal via structure and landing on the metal alloy base, a second metal liner located on a sidewall of the second via portion of the metal via structure, and a dielectric liner located between the second metal liner and the ILD layer.

In yet another embodiment of the present application, the structure includes a metal alloy base located on an electrically conductive structure, and a metal via structure embedded in an interlayer dielectric (ILD) layer and located on the metal alloy base. The metal via structure of this embodiment includes a first via portion and a second via portion in which the first via portion is in direct physical contact with the metal alloy base, and the second via portion is located above, and is in direct physical contact with, the first via portion. The structure of this embodiment includes a first metal liner located on a sidewall and a topmost surface of the first via portion of the metal via structure and landing on a the metal alloy base, and a second metal liner located on a sidewall of the second via portion of the metal via structure and positioned between the second via portion and the ILD layer.

### BRIEF DESCRIPTION OF THE DRAWINGS

FIG. 1 is a cross sectional view of an exemplary structure that can be employed in the present application, the exemplary structure including an electrically conductive structure embedded in a first ILD layer.

FIG. 2 is a cross sectional view of the exemplary structure of FIG. 1 after forming a metal alloy layer on top of the first ILD layer and the electrically conductive structure, and a first metal layer on the metal alloy layer.

FIG. 3 is a cross sectional view of the exemplary structure of FIG. 2 after patterning the first metal layer into a first via portion of a metal via structure.

FIG. 4 is a cross sectional view of the exemplary structure of FIG. 3 after forming a first metal liner on a physically exposed surface of the metal alloy layer and on a sidewall and a topmost surface of the first via portion of the metal via structure.

FIG. 5 is a cross sectional view of the exemplary structure of FIG. 4 after forming a second ILD layer having a topmost surface that is substantially coplanar with a topmost surface of the first metal liner that is located on the topmost surface of the first via portion of the metal via structure.

FIG. 6 is a cross sectional view of the exemplary structure of FIG. 5 after forming a patterned hard mask above the first via portion of the metal via structure.

FIG. 7 is a cross sectional view of the exemplary structure of FIG. 6 after etching the second ILD layer, the first metal liner and the metal alloy layer that are not protected by the patterned hard mask, and removing the patterned hard mask.

FIG. 8 is a cross sectional view of the exemplary structure of FIG. 7 after forming a dielectric cap layer.

FIG. 9 is a cross sectional view of the exemplary structure of FIG. 8 after forming a third ILD layer and patterning the third ILD layer to include a via opening located therein.

FIG. 10 is a cross sectional view of the exemplary structure of FIG. 9 after forming a dielectric spacer along a sidewall of the via opening.

FIG. 11 is a cross sectional view of the exemplary structure of FIG. 10 after forming a second metal liner along a sidewall of the dielectric spacer that is present in the via opening.

FIG. 12 is a cross sectional view of the exemplary structure of FIG. 11 after revealing the first via portion of the metal via structure.

FIG. 13 is a cross sectional view of the exemplary structure of FIG. 12 after forming a second via portion of the metal via structure in direct physical contact with the first via portion of the metal via structure and in the via opening.

FIG. 14 is a cross sectional view of the exemplary structure of FIG. 9 after forming a second metal liner along a sidewall of the via opening.

FIG. 15 is a cross sectional view of the exemplary structure of FIG. 14 after revealing the first via portion of the metal via structure.

FIG. 16 is a cross sectional view of the exemplary structure of FIG. 15 after forming a second via portion of the metal via structure in direct physical contact with the first via portion of the metal via structure and in the via opening.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

For multilevel interconnection of advanced semiconductor devices, metal via structures are used to enable metal-to-metal contact to the metal levels below. Metal via structures typically include a main conductor material such as, for example, W, Cu or Co, and several suitable nucleation, liner and/or barrier layers which are present along a sidewall and a bottom surface of the main conductor material. These layers ensure adequate adhesion to the surrounding ILD layer as well as good nucleation and growth of the main conductor material. Liner and barrier materials typically exhibit high resistivity, and the presence of such high-resistivity liner and barrier layers in a via structure results in high via resistance which negatively impacts device performance. In addition, the various interfaces formed by those liner and barrier layers can add resistance components to the overall via resistance. There is a need for providing a metal via structure having a reduced via resistance.

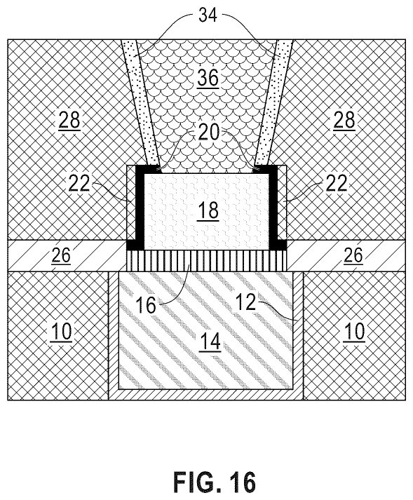

The present application provides a structure (see, for example, FIGS. 13 and 16) that includes a metal via structure located on a metal alloy base 16. The metal via structure includes a first via portion 18 and a second via portion 36 in which the first via portion 18 is in direct physical contact with the metal alloy base 16, and the second via portion 36 is located above, and is in direct physical contact, with the first via portion 18. The metal via structure of the present application lacks nucleation, liner and/or barrier layers covering an entirety of a bottom surface of the metal via structure and thus direct physical contact of the metal structure with the metal alloy base is established. The metal via structure of the present application has a lower via resistance and extends the scalability of metal via structures due to an enlarged process window for low via resistance.

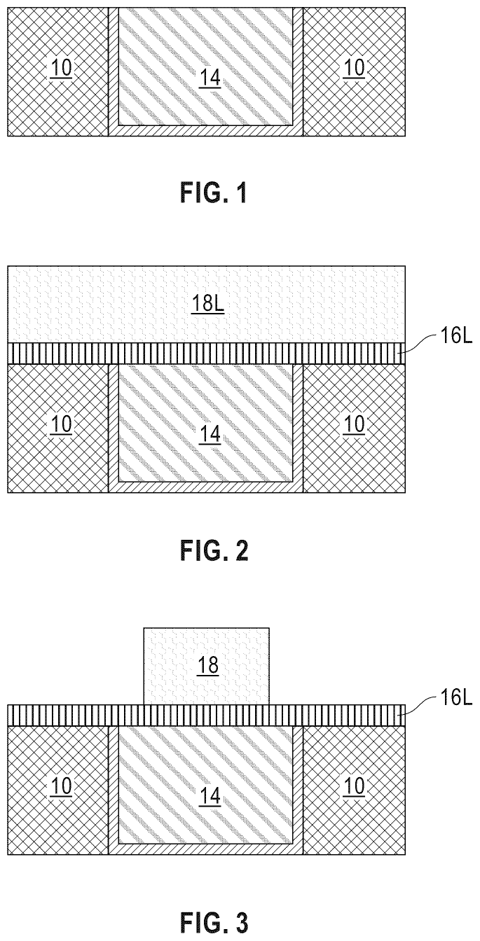

Referring first to FIG. 1, there is illustrated an exemplary structure that can be employed in the present application, the exemplary structure including an electrically conductive structure 14 embedded in a first ILD layer 10. In some embodiments and as is illustrated in FIG. 1, a diffusion barrier liner 12 can be present along a sidewall and a bottom wall of the electrically conductive structure 14. In other embodiments, the diffusion barrier liner 12 can be omitted and thus the diffusion barrier liner 12 is optional. Collectively, the electrically conductive structure 14, (if present) the diffusion barrier liner 12, and the first ILD layer 10 provide a metal (or interconnect) level, Mn, wherein n is any integer starting from 1; the upper limit of ‘n’ can vary and can be predetermined by the manufacturer of a specific integrated circuit. It is noted that although the present application describes and illustrates a single electrically conductive structure 14 embedded in the first ILD layer 10, the present application contemplates embodiments in which more than one electrically conductive structure 14 is embedded in the first ILD layer 10. When more than one electrically conductive structure 14 is present in the first ILD layer 10, some or all of the electrically conductive structures can be processed to include a metal via structure in accordance with the present application.

In some embodiments, the electrically conductive structure 14 can extend entirely through the first ILD layer 10. In other embodiments, the electrically conductive structure 14 extends partially through the first ILD layer 10 and in such embodiments, the electrically conductive structure 14 can be connected to another electrically conductive structure such as, for example, a metal line and/or a metal via, that can be located directly beneath, and in contact with, the electrically conductive structure 14.

Although not illustrated in any of the drawings of the present application, a substrate can be located beneath metal level, Mn. The substrate can include a front-end-of-the-line (FEOL) level including one or more semiconductor devices, such as, for example, field effect transistors located on a semiconductor material; a middle-of-the-line (MOL) level including a plurality of metal contact structures embedded in a MOL dielectric material layer; at least one lower interconnect level that includes a plurality of lower interconnect structures embedded in a lower interconnect dielectric material layer; or any combination thereof. In one example, the substrate includes a FEOL level and a MOL level.

The metal level, Mn, can be formed utilizing techniques that are known to those skilled in the art. In one embodiment, a damascene process can be used in forming metal level, Mn. A damascene process can include forming an opening into the first ILD layer 10, filling the opening with an optional diffusion barrier layer, and an electrically conductive material and, if needed performing a planarization process such as, for example, chemical mechanical planarization (CMP) to remove the optional diffusion barrier layer and the electrically conductive material from the topmost surface of the first ILD layer 10. The diffusion barrier layer that remains in the opening can be referred to herein as diffusion barrier liner 12, and the electrically conductive material that remains in the opening can be referred to herein as the electrically conductive structure 14. In some embodiments, and as shown in FIG. 1, the electrically conductive structure 14 has a topmost surface that is coplanar with a topmost surface of the first ILD layer 10 as well as with a topmost surface of the diffusion barrier liner 12, if the same is present.

The first ILD layer 10 can be composed of a dielectric material such as, for example, silicon dioxide, silicon nitride, undoped silicate glass (USG), fluorosilicate glass (FSG), borophosphosilicate glass (BPSG), a spin-on low-k dielectric material, a chemical vapor deposition (CVD) low-k dielectric material or any combination thereof. The term “low-k” as used throughout the present application denotes a dielectric material that has a dielectric constant of less than 4.0. All dielectric constants mentioned herein are measured in a vacuum unless otherwise noted. Illustrative low-k dielectric materials that can be used as the first ILD layer 10 include, but are not limited to, silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. Although not shown, the first ILD layer 10 can include a multilayered structure that includes at least two different dielectric materials stacked one atop the other. The first ILD layer 10 can be formed utilizing a deposition process including, for example, chemical vapor deposition (CVD), plasma enhanced chemical vapor deposition (PECVD), evaporation or spin-on coating.

The diffusion barrier layer (and thus the resultant diffusion barrier liner 12) that can optionally be employed in the present application includes a diffusion barrier material (i.e., a material that serves as a barrier to prevent a conductive material such as copper from diffusing there through). Examples of diffusion barrier materials that can be used in providing the diffusion barrier layer (and thus the resultant diffusion barrier liner 12) include, but are not limited to, Ta, TaN, Ti, TiN, Ru, RuN, RuTa, RuTaN, W, or WN; in some instances of the present application chemical symbols, as found in the Periodic Table of Elements, are used instead of the full names of the elements or compounds. In some embodiments, the diffusion barrier material can include a material stack of diffusion barrier materials. In one example, the diffusion barrier material can be composed of a stack of Ta/TaN. The diffusion barrier layer can be formed by a deposition process such as, for example, CVD, PECVD, or physical vapor deposition (PVD).

The electrically conductive material that provides the electrically conductive structure 14 can include an electrically conductive metal and/or an electrically conductive metal alloy. Illustrative examples of electrically conductive metals include, but are not limited to, Cu, W, Al, Co, or Ru. An illustrative example of an electrically conductive metal alloy includes Cu—Al alloy. The electrically conductive material that provides electrically conductive structure 14 can be formed by a deposition process such as, for example, CVD, PECVD, PVD, sputtering or platting. In some embodiments, a reflow anneal can follow the deposition of the electrically conductive material that provides electrically conductive structure 14. The electrically conductive structure 14 can be a metal line, a metal via or a combination of a metal line/metal via. The electrically conductive structure 14 is embedded in the first ILD layer 10.

Referring now to FIG. 2, there is illustrated the exemplary structure of FIG. 1 after forming a metal alloy layer 16L on top of the first ILD layer 10 and the electrically conductive structure 14, and a first metal layer 18L on the metal alloy layer 16L. The metal alloy layer 16L is an electrically conductive metal alloy that includes at least one noble metal which is resistant to oxidation. It is noted that the electrically conductive material alloy employed as the metal alloy layer 16L is compositionally different from any metal alloy that may be present in the electrically conductive structure 14. The electrically conductive metal alloys that can be used as the metal alloy layer 16L include, for example, PtW, IrW, or PtIr. The metal alloy layer 16L can be formed by a deposition process such as, for example, CVD, PECVD, PVD, sputtering or plating. The first metal layer 18L is composed of a first electrically conductive metal such as, for example, Cu, W, Al, Co, or Ru. The first metal layer 18L can be formed by a deposition process such as, for example, CVD, PECVD, PVD, sputtering or plating. In some embodiments, the metal layer alloy layer 16L has a first thickness and the first metal layer 18L has a second thickness in which the second thickness is greater than the first thickness. The metal alloy layer 16L is in direct contact with the electrically conductive structure 14 that is embedded in the first ILD layer 10.

Referring now to FIG. 3, there is illustrated the exemplary structure of FIG. 2 after patterning the first metal layer 18L into a first via portion 18 of a metal via structure; in the present application the metal via structure includes first via portion 18 and a second via portion 36 to be subsequently formed. Notably, the metal via structure of the present application includes separate via portions, i.e., the first via portion 18 and the second via portion 36, that are formed in separate processing steps. The patterning of the first metal layer 18L includes lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. The first via portion 18 of the metal via structure typically has a second critical dimension, i.e., width, which is less than a first critical dimension, i.e., width, of the electrically conductive structure 14 that is located beneath the first via portion 18 of the metal via structure.

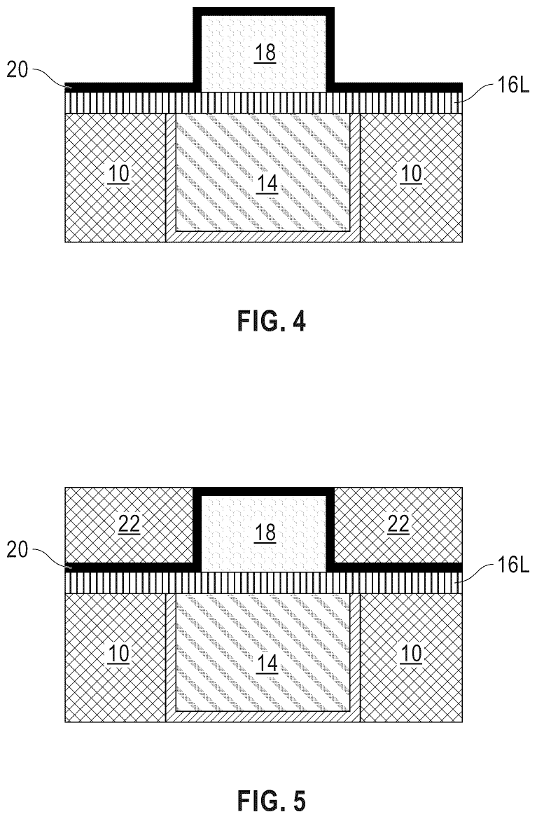

Referring now to FIG. 4, there is illustrated the exemplary structure of FIG. 3 after forming a first metal liner 20 on a physically exposed surface of the metal alloy layer 16L and on a sidewall and a topmost surface of the first via portion 18 of the metal via structure. The first metal liner 20 is composed of a first metal liner material such as, for example, TiW, TiN, TaN, or WN. The first metal liner 20 can be formed by a deposition process such as, for example, CVD, PECVD, atomic layer deposition (ALD) or PVD. The first metal liner 20 can be a conformal layer (as illustrated in FIG. 4) or a non-conformal layer (not illustrated in the present application). As used herein, the term “conformal layer” denotes that a material layer has a vertical thickness along horizontal surfaces that is substantially the same (i.e., within ±5%) as the lateral thickness along vertical surfaces.

Referring now to FIG. 5, there is illustrated the exemplary structure of FIG. 4 after forming a second ILD layer 22 having a topmost surface that is substantially coplanar with a topmost surface of the first metal liner 20 that is located on the topmost surface of the first via portion 18 of the metal via structure. The second ILD layer 22 can include a dielectric material as mentioned above for the first ILD layer 10. The dielectric material that provides the second ILD layer 22 can be compositionally the same as, or compositionally different from, the dielectric material that provides the first ILD layer 10. The second ILD layer 22 can be formed by a deposition process such as, for example, CVD, PECVD, evaporation or spin-on coating. A planarization process such as, for example, CMP, follows the deposition of the dielectric material that provides the second ILD layer 22.

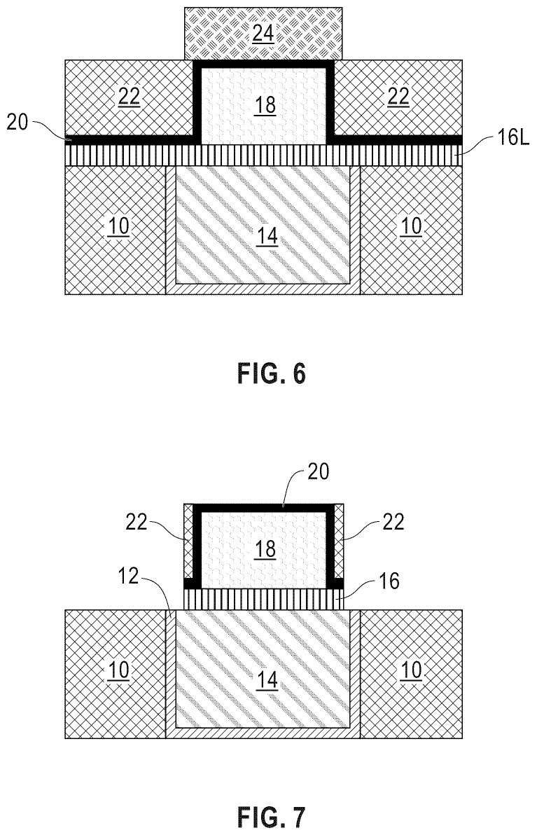

Referring now to FIG. 6, there is illustrated the exemplary structure of FIG. 5 after forming a patterned hard mask 24 above the first via portion 18 of the metal via structure. The patterned hard mask 24 has a third critical dimension, i.e., width, which is greater than the second critical dimension, i.e., width, of the first via portion 18 of the metal via structure, yet it is typically less than the first critical dimension, i.e., width, of the electrically conductive structure 14. The patterned hard mask 24 is composed of a dielectric hard mask material such as, for example, silicon dioxide, silicon nitride, and/or silicon oxynitride. The patterned hard mask 24 is formed by first depositing a layer of dielectric hard mask material, and then a lithographic patterning process, as defined above is used to pattern the as-deposited layer of dielectric hard mask material.

Referring now to FIG. 7, there is illustrated the exemplary structure of FIG. 6 after etching the second ILD layer 22, the first metal liner 20 and the metal alloy layer 18L that are not protected by the patterned hard mask 24, and removing the patterned hard mask 24. The etching can include one or more etching processes. The one or more etching processes stop on a surface of the first ILD layer 10. After etching, a portion of the second ILD layer 22, the first metal liner 20 and the metal alloy layer 18L remain beneath the patterned hard mask 24. The remaining metal alloy layer 18L is now referred to as a metal alloy base 16. Metal alloy base 16 ensures metal-to-metal contact between the first via portion 18 of the metal via structure and the electrically conductive structure 14 without metal oxidation. Metal oxidation is not warranted since it increases the resistance of the via structure. The presence of metal alloy layer 18L containing one or more noble metals provides metal alloy base 18 which ensures a clean interface without oxidation between the metal via structure and the underlying metal level.

As is illustrated in FIG. 7, first metal liner 20 is located along a sidewall and a topmost surface of the first via portion 18. A portion of the second ILD layer 22 can remain along a sidewall of the first metal liner 20. The removal of the patterned hard mask 24 includes the use of any material removal process that is selective in removing the patterned hard mask 24.

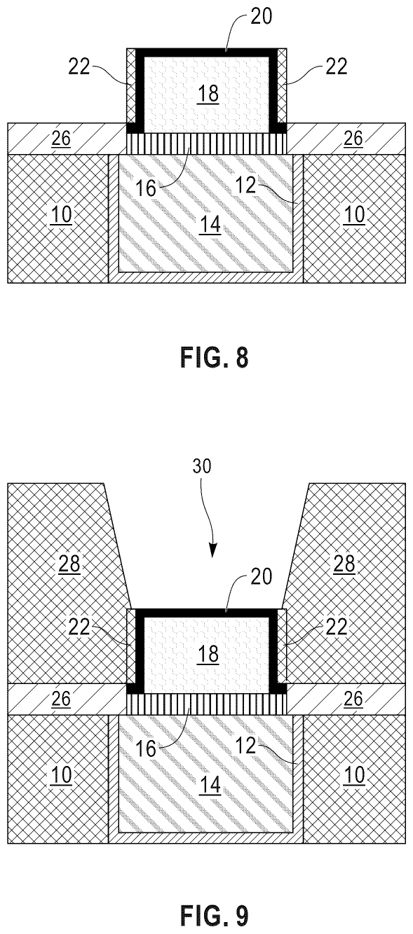

Referring now to FIG. 8, there is illustrated the exemplary structure of FIG. 7 after forming a dielectric cap layer 26. Dielectric cap layer 26 is optional and thus can be omitted in some embodiments of the present application. Dielectric cap layer 26 is composed of a dielectric capping material which is compositionally different from the dielectric material that provides the first ILD layer 10. The dielectrically capping material that provides the dielectric cap layer 26 can include, but is not limited to, silicon nitride (SiN), or a dielectric containing atoms of silicon, nitrogen and carbon (i.e., SiNC). The dielectric cap layer 26 can be formed by a deposition process including, but not limited to, atomic layer deposition (ALD), CVD, PECVD or PVD, followed by a planarization process such as, for example, CMP, and thereafter followed by an etch back process. As is illustrated in FIG. 8, the dielectric cap layer 26 is formed on top of the first ILD layer 10, the diffusion barrier layer 12, if the same is present, and on top of a portion of the electrically conductive structure 14. The dielectric cap layer 26 is also present along a sidewall of each of the metal alloy base 16 and the first metal liner 20. The dielectric cap layer 26 has topmost surface that is higher than a topmost surface of the metal alloy base 16. In embodiments of the present application, the topmost surface of the dielectric cap layer 26 is between a topmost surface and a bottom surface of the first via portion 18 of the metal via structure.

Referring now to FIG. 9, there is illustrated the exemplary structure of FIG. 8 after forming a third ILD layer 28 and patterning the third ILD layer 28 to include a via opening 30 located therein. The third ILD layer 28 can include a dielectric material as mentioned above for the first ILD layer 10. The dielectric material that provides the third ILD layer 28 can be compositionally the same as, or compositionally different from, the dielectric material that provides the first ILD layer 10 and/or the dielectric material that provides the second ILD layer 22. When the third ILD layer 28 and the second ILD layer 22 are composed of a compositionally same dielectric material, no material interface is present between the two ILD layers. When the third ILD layer 28 is composed of a compositionally different dielectric material than the second ILD layer 22, a material interface is present between the two ILD layers. The third ILD layer 28 can be formed by a deposition process such as, for example, CVD, PECVD, evaporation or spin-on coating. A planarization process such as, for example, CMP, follows the deposition of the dielectric material that provides the third ILD layer 28. The patterning of the third ILD layer 28 includes a lithographic patterning process as defined above. The via opening 30 that is formed can have a substantially perpendicular sidewall, or it can have a tapered (i.e., slanted) sidewall as is illustrated in FIG. 9. In the case of the via opening 30 having a tapered (i.e., slanted) sidewall, the volume of the via opening 30 can decrease from top to bottom as is illustrated in FIG. 9.

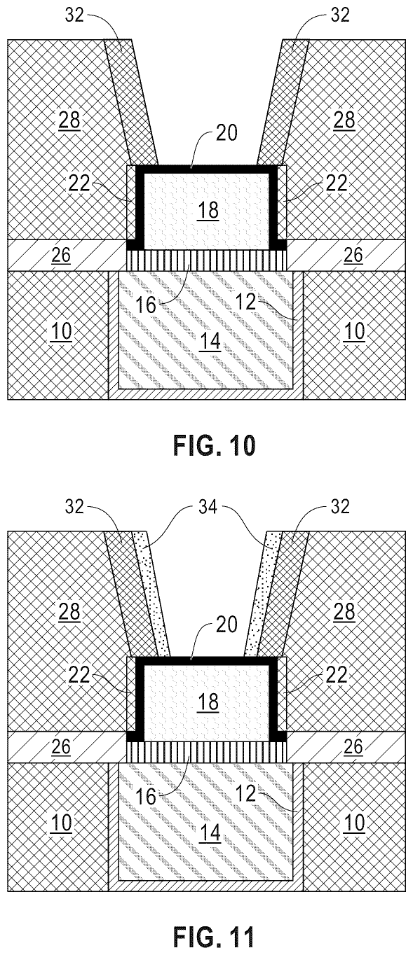

Referring now to FIG. 10, there is illustrated the exemplary structure of FIG. 9 after forming a dielectric spacer 32 along a sidewall of the via opening 30. Dielectric spacer 32 is composed of any dielectric spacer material such as, for example, silicon dioxide, silicon nitride, SiBCN, SiOCN or SiOC; the dielectric spacer material is typically compositionally different from the dielectric material that provides the third ILD layer 28 and/or the second ILD layer 22. The dielectric spacer 32 is formed by first depositing (e.g., CVD, PECVD, or PVD) a layer of dielectric spacer material, and then a spacer etch back process is used in converting the layer of dielectric spacer material into the dielectric spacer 32. The dielectric spacer 32 has a topmost surface that is substantially coplanar with a topmost surface of the third ILD layer 28. The dielectric spacer 32 lands on a topmost surface of the remaining second ILD layer 22 and a portion of the topmost surface of the first metal liner 20 that is located on the sidewall and the topmost surface of the metal alloy base 16. Note that the dielectric spacer 32 does not fill an entirety of the via opening 30.

Referring now to FIG. 11, there is illustrated the exemplary structure of FIG. 10 after forming a second metal liner 34 along a sidewall of the dielectric spacer 32 that is present in the via opening 30. The second metal liner 34 is composed of a second metal liner material such as, for example, TiW, TiN, TaN, or WN, which is compositionally different from the first metal liner material such that an etch selective exists between the first metal liner 20 and the second metal liner 34. The second metal liner 34 is formed by first depositing (e.g., CVD, PECVD, or PVD) a layer of metal liner material, and then an etch back process is used in converting the layer of second metal liner material into the second metal liner 34. The second metal liner 34 has a topmost surface that is substantially coplanar with a topmost surface of the third ILD layer 28 and the dielectric spacer 32. In this embodiment, the second metal liner 32 is spaced apart from the third ILD layer 28 by the dielectric spacer 32. The second metal liner 34 lands on the topmost surface of the first metal liner 20 that is located on the sidewall and the topmost surface of the metal alloy base 16. Note that the second metal liner 34 does not fill an entirety of the via opening 30.

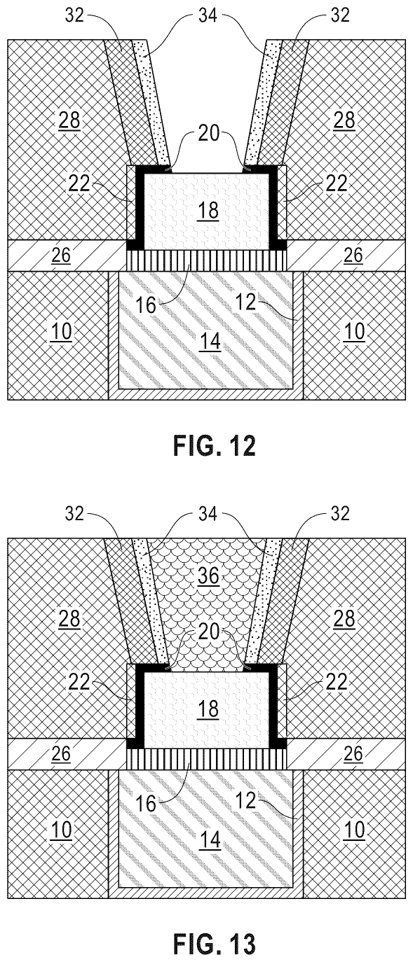

Referring now to FIG. 12, there is illustrated the exemplary structure of FIG. 11 after revealing the first via portion 18 of the metal via structure. The revealing of the first via portion 18 of the metal via structure includes an etching process that is selective in removing a horizontal portion of the first metal liner 20 that is located on a topmost surface of the first via portion 18 of the metal via structure. Note that the second metal liner 34 and the dielectric spacer 32 protect the first metal liner 20 that is located directly beneath those two elements. As a result of this etching process, the first metal liner 20 is no longer continuously present along the topmost surface of the first via portion 18 of the metal via structure.

Referring now to FIG. 13, there is illustrated the exemplary structure of FIG. 12 after forming a second via portion 36 of the metal via structure above, and in direct physical contact with, the first via portion 18 of the metal via structure and in the via opening 30. The second via portion 36 of the metal via structure is composed of a second electrically conductive metal including, for example, Cu, W, Al, Co, or Ru. The second electrically conductive metal can be compositionally the same as, or compositionally different from, the first electrically conductive metal that provides the first via portion 18. As is illustrated, the second via portion 36 is in direct physical contact with the first via portion 18. The second via portion 36 is formed in a remaining volume of the via opening 30 and between the second metal liner 34 that is also present in the via opening 30. The second via portion 36 has a topmost surface that is substantially coplanar with a topmost surface of each of the third ILD layer 28, dielectric spacer 32 and second metal liner 34. The second via portion 36 can be formed by deposition of the second electrically conductive metal, followed by a planarization process. The second via portion 36 can have a substantially perpendicular sidewall, or a slanted sidewall as illustrated in FIG. 13. In the illustrated embodiment, the second via portion 36 has an upper portion having a critical dimension that is greater than a lower portion of the second via portion 36 In some embodiments of the present application, the second via portion 36 has a tapered sidewall and is funnel shaped.

Notably, FIG. 13 illustrates an exemplary structure in accordance with an embodiment of the present application. The exemplary structure illustrated in FIG. 13 includes metal alloy base 16 located on electrically conductive structure 14, and a metal via structure embedded in an ILD (i.e., third ILD layer 28) and located on the metal alloy base 16. The metal via structure of this embodiment includes first via portion 18 and second via portion 36 in which the first via portion 18 is in direct physical contact with the metal alloy base 16, and the second via portion 36 is located above, and is in direct physical contact with, the first via portion 18. The structure further includes first metal liner 20 located on a sidewall and a topmost surface of the first via portion 18 of the metal via structure and landing on the metal alloy base 16, second metal liner 34 located on a sidewall of the second via portion 36 of the metal via structure, and dielectric liner 32 located between the second metal liner 34 and the ILD layer (i.e., third ILD layer 28).

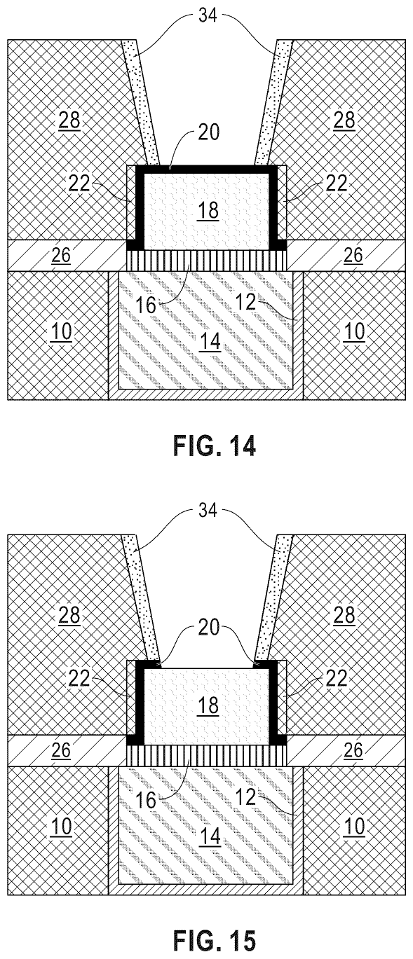

Referring now to FIG. 14, there is illustrated the exemplary structure of FIG. 9 after forming a second metal liner 34 along a sidewall of the via opening 30. The second metal liner 34 used in this embodiment is the same as that described above in regard to the second metal liner 34 illustrated in FIG. 11. The second metal liner 34 shown in FIG. 14 thus includes materials as mentioned above, and is formed used the same technique mentioned above in forming the second metal liner 34 illustrated in FIG. 11. In this embodiment, the second metal liner 34 is in direct contact with a sidewall of the third ILD layer 28 that is exposed in via opening 30. In the previous embodiment and as shown in FIG. 11, the second metal liner 34 is spaced apart from the sidewall of the third ILD layer 28 that is exposed in via opening 30 by dielectric spacer 32.

Referring now to FIG. 15, there is illustrated the exemplary structure of FIG. 14 after revealing the first via portion 18 of the metal via structure. The revealing of the first via portion 18 of the metal via structure includes an etching process that is selective in removing a horizontal portion of the first metal liner 20 that is located on a topmost surface of the first via portion 18 of the metal via structure. Note that the second metal liner 34 protects the first metal liner 20 that is located directly beneath that element. As a result of this etching process, the first metal liner 20 is no longer continuously present along the topmost surface of the first via portion 18 of the metal via structure.

Referring now to FIG. 16, there is illustrated the exemplary structure of FIG. 15 after forming a second via portion 36 of the metal via structure above, and in direct physical contact with, the first via portion 18 of the metal via structure and in the via opening 30. The second via portion 36 of this embodiment is the same as second via portion 36 illustrated in FIG. 13. The second via portion 36 shown in FIG. 16 thus includes materials as mentioned above, and is formed used the same technique mentioned above in forming the second via portion 36 illustrated in FIG. 13. The second via portion 36 of this embodiment has a topmost surface that is substantially coplanar with a topmost surface of each of the third ILD layer 28, and second metal liner 34. In the illustrated embodiment, the second via portion 36 has an upper portion having a critical dimension that is greater than a lower portion of the second via portion 36. In some embodiments of the present application, the second via portion 36 has a tapered sidewall and is funnel shaped.

Notably, FIG. 16 illustrates another exemplary structure in accordance with an embodiment of the present application. The exemplary structure illustrated in FIG. 16 includes metal alloy base 16 located on electrically conductive structure 14, and a metal via structure embedded in an ILD (i.e., third ILD layer 28) and located on the metal alloy base 16. The metal via structure of this embodiment includes first via portion 18 and second via portion 36 in which the first via portion 18 is in direct physical contact with the metal alloy base 16, and the second via portion 36 is located above, and is in direct physical contact with, the first via portion 18. The structure further includes first metal liner 20 located on a sidewall and a topmost surface of the first via portion 18 of the metal via structure and landing on the metal alloy base 16, and second metal liner 34 located on a sidewall of the second via portion 36 of the metal via structure, and a dielectric liner 32 located between the second metal liner 34 and positioned between the second via portion 36 and the ILD layer.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A structure comprising:
a metal via structure located on a metal alloy base and comprising a first via portion and a second via portion, wherein the first via portion is in direct physical contact with the metal alloy base, and the second via portion is located above, and in direct physical contact with, the first via portion.

2. The structure of claim 1, further comprising a first metal liner located on a sidewall and a topmost surface of the first via portion of the metal via structure and landing on the metal alloy base, and a second metal liner located on a sidewall of the second via portion of the metal via structure.

3. The structure of claim 2, wherein the second metal liner lands on a topmost surface of the first metal liner.

4. The structure of claim 2, further comprising a dielectric spacer located adjacent to the second metal liner, wherein the dielectric spacer is spaced apart from the second via portion by the second metal liner.

5. The structure of claim 1, wherein the second via portion has an upper portion having a critical dimension that is greater than a lower portion of the second via portion.

6. The structure of claim 1, wherein the first via portion has a substantially perpendicular sidewall.

7. The structure of claim 1, wherein the second via portion has a sidewall and is funnel shaped.

8. The structure of claim 1, further comprising a dielectric cap layer located adjacent to the metal alloy base.

9. The structure of claim 1, wherein the first via portion is composed of a first electrically conductive metal and the second via portion is composed of a second electrically conductive metal, wherein the second electrically conductive metal is compositionally the same as the first electrically conductive metal.

10. The structure of claim 1, wherein the first via portion is composed of a first electrically conductive metal and the second via portion is composed of a second electrically conductive metal, wherein the second electrically conductive metal is compositionally different from the first electrically conductive metal.

11. A structure comprising:
a metal alloy base located on an electrically conductive structure;
a metal via structure embedded in an interlayer dielectric (ILD) layer and located on the metal alloy base, the metal via structure comprising a first via portion and a second via portion, wherein the first via portion is in direct physical contact with the metal alloy base, and the second via portion is located above, and is in direct physical contact with, the first via portion;
a first metal liner located on a sidewall and a topmost surface of the first via portion of the metal via structure and landing on a the metal alloy base;
a second metal liner located on a sidewall of the second via portion of the metal via structure; and
a dielectric liner located between the second metal liner and the ILD layer.

12. The structure of claim 11, wherein the second metal liner lands on the topmost surface of the first metal liner.

13. The structure of claim 11, wherein the second via portion has an upper portion having a critical dimension that is greater than a lower portion of the second via portion.

14. The structure of claim 11, wherein the first via portion has a substantially perpendicular sidewall.

15. The structure of claim 11, wherein the second via portion has a tapered sidewall and is funnel shaped.

16. A structure comprising:
a metal alloy base located on an electrically conductive structure;
a metal via structure embedded in an interlayer dielectric (ILD) layer and located on the metal alloy base, the metal via structure comprising a first via portion and a second via portion, wherein the first via portion is in direct physical contact with the metal alloy base, and the second via portion is located above, and is in direct physical contact with, the first via portion;
a first metal liner located on a sidewall and a topmost surface of the first via portion of the metal via structure and landing on a the metal alloy base; and a second metal liner located on a sidewall of the second via portion of the metal via structure and positioned between the second via portion and the ILD layer.

17. The structure of claim 16, wherein the second metal liner lands on the topmost surface of the first metal liner.

18. The structure of claim 16, wherein the second via portion has an upper portion having a critical dimension that is greater than a lower portion of the second via portion.

19. The structure of claim 16, wherein the first via portion has a substantially perpendicular sidewall.

20. The structure of claim 16, wherein second upper via portion has a tapered sidewall and is funnel shaped.
